(19) United States
(12) Patent Application Publication
(10) Pub. No.: US 2014/0264247 A1
(43) Pub. Date: Sep. 18, 2014

(54) Resistive Memory Cell with Reduced Bottom Electrode

(71) Applicant: Microchip Technology Incorporated, Chandler, AZ (US)

(72) Inventors: Sonu Daryanani, Tempe, AZ (US); Bomy Chen, Newark, CA (US)

(21) Appl. No.: 14/183,792

(22) Filed: Feb. 19, 2014

Related U.S. Application Data
(60) Provisional application No. 61/780,317, filed on Mar. 13, 2013.

(51) Int. Cl. H01L 45/00

(52) U.S. Cl. CPC H01L 45/1253; H01L 45/16
USPC 257/4; 438/382

(57) ABSTRACT

A resistive memory cell may include a ring-shaped bottom electrode, a top electrode, and an electrolyte layer arranged between the bottom and top electrodes. A ring-shaped bottom electrode may be formed by forming a dielectric layer over a bottom electrode contact, etching a via in the dielectric layer to expose at least a portion of the bottom electrode contact, depositing a conductive via liner over the dielectric layer and into the via, the via liner deposited in the via forming a ring-shaped structure in the via and a contact portion in contact with the exposed bottom electrode contact, the ring-shaped structure defining a radially inward cavity of the ring-shaped structure, and filling the cavity with a dielectric fill material, such that the ring-shaped structure of the via liner forms the ring-shaped bottom electrode, depositing an electrolyte layer over the bottom electrode, and depositing a top electrode over the electrolyte layer.

### CROSS-REFERENCE TO RELATED APPLICATIONS

This application claims the benefit of U.S. Provisional Application No. 61/780,317 filed on Mar. 13, 2013, which is incorporated herein in its entirety.

### TECHNICAL FIELD

The present disclosure relates to resistive memory cells, e.g., conductive bridging random access memory (CBRAM) or resistive random-access memory (ReRAM) cells, having an asymmetrical structure (e.g., including a ring-shaped bottom electrode) providing a reduced area for the formation of conductive paths (e.g., conductive filaments or vacancy chains).

### BACKGROUND

Resistive memory cells, such as conductive bridging memory (CBRAM) and resistive RAM (ReRAM) cells are a new type of non-volatile memory cells that provide scaling and cost advantages over conventional Flash memory cells. A CBRAM is based on the physical re-location of ions within a solid electrolyte. A CBRAM memory call can be made of two solid metal electrodes, one relatively inert (e.g., tungsten) the other electrochemically active (e.g., silver or copper), with a thin film of the electrolyte between them. The fundamental idea of a CBRAM cell is to create programmable conducting filaments, formed by either single or very few nanometer-scale ions across a normally non-conducting film through the application of a bias voltage across the non-conducting film. The non-conducting film is referred to as the electrolyte since it creates the filament through an oxidation/reduction process much like in a battery. In a ReRAM cell the conduction is through creation of a vacancy chain in an insulator. The creation of the filament/vacancy-chain creates an on-state (high conduction between the electrodes), while the dissolution of the filament/vacancy-chain is by applying a similar polarity with Joule heating current or an opposite polarity but at smaller currents to revert the electrolyte/insulator back to its nonconductive off-state.

A wide range of materials have been demonstrated for possible use in resistive memory cells, both for the electrolyte and the electrodes. One example is the Cu/SiOx based cell in which the Cu is the active metal-source electrode and the SiOx is the electrolyte.

One common problem facing resistive memory cells is the on-state retention, i.e., the ability of the conductive path (filament or vacancy chain) to be stable, especially at the elevated temperatures that the memory parts would typically be qualified to (85 C/125 C).

FIG. 1 shows a conventional CBRAM cell 1A, having a top electrode 10 (e.g., copper) arranged over a bottom electrode 12 (e.g., tungsten), with the electrolyte or middle electrode 14 (e.g., SiO₂) arranged between the top and bottom electrodes. Conductive filaments 18 propagate from the bottom electrode 12 to the top electrode 10 through the electrolyte 14 when a bias voltage is applied to the cell 1A. This structure has various potential limitations or drawbacks. For example, the effective cross-sectional area for filament formation, referred to herein as the effective filament formation area indicated as A_{FF}, or alternatively the “confinement zone,” is relatively large and unconfined, making the filament formation area susceptible to extrinsic defects. Also, multi-filament root formation may be likely, due to a relatively large area, which may lead to weaker (less robust) filaments. In general, the larger the ratio between the diameter or width of the effective filament formation area A_{FF} (indicated by “x”) to the filament propagation distance from the bottom electrode 12 to the top electrode 10 (in this case, the thickness of the electrolyte 14, indicated by “y”), the greater the chance of multi-root filament formation. Further, a large electrolyte volume surrounds the filament, which provides diffusion paths for the filament and thus may provide poor retention. Thus, restricting the volume of the electrolyte material in which the conductive path forms may provide a more robust filament due to spatial confinement. The volume of the electrolyte material in which the conductive path forms may be restricted by reducing the area in contact between the bottom electrode 12 and the electrolyte 14.

As used herein, “conductive path” refers a conductive filament (e.g., in a CBRAM cell), vacancy chain (e.g., in an oxygen vacancy based ReRAM cell), or any other type of conductive path for connecting the bottom and top electrodes of a non-volatile memory cell (typically through an electrolyte layer or region arranged between the bottom and top electrodes). As used herein the “electrolyte layer” or “electrolyte region” refers to an electrolyte/insulator/memory layer or region between the bottom and top electrodes through which the conductive path propagates.

FIG. 2 shows certain principles of a CBRAM cell formation. Conductive paths 18 may form and grow laterally, or branch into multiple parallel paths. Further, locations of the conductive paths may change with each program/erase cycle. This may contribute to a marginal switching performance, variability, high-temp retention issues, and/or switching endurance. Restricting switching volume has been shown to benefit the operation. These principles apply to ReRAM and CBRAM cells. A key obstacle for adoption of these technologies is switching uniformity.

### SUMMARY

According to various embodiments, a non-volatile memory cell structure, and associated manufacturing process, provides a reduced area of contact between the bottom electrode and the electrolyte layer, thus restricting the area in which a conductive path can form, i.e., the “confinement zone,” and thereby create thicker, single conductive path root memory cells (e.g., CBRAM cells and ReRAM cells) having improved switching performance, retention performance, and/or reliability. For example, the confinement zone may be defined by a narrow ring having a width of less than 100 Å.

In one embodiment, a resistive memory cell includes a ring-shaped bottom electrode, a top electrode, and an electrolyte layer arranged between the bottom and top electrodes.

In another embodiment, a method for forming a resistive memory cell comprises forming a ring-shaped bottom electrode by a process including: forming a dielectric layer over a bottom electrode contact, etching a via in the dielectric layer to expose at least a portion of the bottom electrode contact, depositing a conductive via liner over the dielectric layer and into the via, the via liner deposited in the via forming a ring-shaped structure in the via and a contact portion in contact with the exposed bottom electrode contact, the ring-shaped structure defining a radially inward cavity of the ring-shaped structure, and filling the cavity with a dielectric fill material, such that the ring-shaped structure of the via liner forms the ring-shaped bottom electrode, depositing an electrolyte layer over the bottom electrode, and depositing a top electrode over the electrolyte layer.

### BRIEF DESCRIPTION OF THE FIGURES

Example embodiments are discussed below with reference to the drawings, in which:

FIG. 1 shows an example conventional CBRAM cell;

FIG. 2 shows certain principles of CBRAM cell formation;

FIG. 3 shows a cross-section of an example resistive memory cell structure (e.g., a CBRAM or ReRAM cell) having a ring-shaped bottom electrode, according to an example embodiment;

FIGS. 4A-4B2 illustrate aspects of a conventional continuous bottom electrode structure;

FIGS. 5A-5B2 illustrate aspects of a ring-shaped bottom electrode structure according to an example embodiment of the present invention, to show one advantage of the ring-shaped bottom electrode structure as compared to a conventional continuous bottom electrode structure;

FIGS. 6A-6D illustrate an example process for creating a memory cell structure having a ring-shaped bottom electrode, according to one embodiment; and

FIG. 7 illustrates an example resistive memory cell structure having a ring-shaped bottom electrode, according to an example embodiment.

### DETAILED DESCRIPTION

FIG. 3 illustrates a cross-section of an example structure 100 for a resistive memory cell (e.g., a CBRAM or ReRAM cell) having a ring-shaped bottom electrode 102 formed in an interlayer dielectric layer 104, an electrolyte layer 106 and top electrode 108 formed over the bottom electrode 102 such that the electrolyte layer 106 is arranged between the bottom electrode 102 and top electrode 108, and bit line(s) 110 connected to the top electrode 108.

Each of the various component regions of structure 100 may be formed from any suitable material and formed in any suitable manner. For example, ring-shaped bottom electrode 102 may be formed from TiN or any other suitable bottom electrode material; top electrode 108 may be formed from Cu, e.g., a very thin Cu layer (e.g., 10-30 nm/5-15 nm) formed by PVD, or any other suitable top electrode material; electrolyte layer 106 may be formed from a thin layer (e.g., 30 Å-150 Å) of high quality SiO2 or SiO or any other suitable electrolyte material; and bit line(s) 110 may be formed from TaN or any other suitable bit line material.

An example filament, e.g., metal bridge, propagated from the ring-shaped bottom electrode 102 to the top electrode 108 through the electrolyte layer 106 is indicated at 120. The ring-shaped bottom electrode 102 provides a substantially reduced contact area between the bottom electrode 102 and overlying electrolyte layer 104 as compared with a solid bottom electrode structure, thus providing a reduced confinement zone. In this example, the ring-shaped bottom electrode 102 has a thickness (x) of less than 100 Å. Providing a bottom electrode thickness (x) less than a thickness (y) of the electrolyte layer (i.e., x/y<1) may provide a particularly reduced chance of multiple conductive path formation.

FIGS. 4A-4B2 and FIGS. 5A-5B2 illustrate aspects of a conventional continuous bottom electrode structure (FIGS. 4A-4B2) and a ring-shaped bottom electrode structure according to an embodiment of the present invention (FIGS. 5A-5B2), to show one advantage of the ring-shaped bottom electrode structure. In particular, FIG. 4A shows a cross-section of a filament formation, and FIGS. 4B1 and 4B2 show a top view of the formation of multiple filaments, for a conventional cell structure having a continuous bottom electrode 102′, a top electrode 108′, and a electrolyte layer 106′ between the continuous bottom electrode 102′ and the top electrode 108′. Likewise, FIG. 5A shows a cross-section of a filament formation, and FIGS. 5B1 and 5B2 show a top view of the formation progression of a single filament, for a cell structure according to an embodiment of the present invention having a ring-shaped bottom electrode 102, a top electrode 108, and a electrolyte layer 106 between the ring-shaped bottom electrode 102 and the top electrode 108.

During SET (filament formation), a decreased number, and an increased thickness, of filament roots is preferred. In the conventional structure shown in FIGS. 4A-4B2, the volume of the electrolyte 106′ in which filaments 120 may form has a relatively large horizontal/vertical length ratio (e.g., x/y>5). In contrast, in the ring-shaped bottom electrode structure 100 disclosed herein, the volume of the electrolyte 106 in which filament(s) 120 may form has a relatively small horizontal/vertical length ratio (e.g., x/y<1). As shown, the ring-shaped bottom electrode structure disclosed herein may provide fewer, but thicker, filament roots, thus providing an advantage over the conventional structure.

FIGS. 6A-6D illustrate an example process for creating a memory cell structure 100 having a ring-shaped bottom electrode 102, according to one embodiment. As shown in FIG. 6A, a via 150 is etched through a dielectric 152 (e.g., SiN) down to a bottom electrode contact 154 (e.g., Cu). The via 150 may have any suitable cross-sectional shape, e.g., circular, oval, elliptical, rectangular, square, etc. The bottom electrode contact 154 may be connected to a circuit or electronic components (e.g., a transistor or other controlling device) via a conductive path 156, which may be formed and connected to bottom electrode contact 154 in any suitable manner, e.g., from below as shown, or from above in any known manner. The bottom electrode contact 154 and/or conductive path 156 may be formed in an inter-layer dielectric 158 (e.g., SiO₂).

As shown in FIG. 6B, a via liner 160 (e.g., TiN) is then deposited and a dielectric fill is performed to fill the remaining via opening with a dielectric 162, in this example an oxide (e.g., SiO₂). As shown in FIG. 6C, a Chemical Mechanical Planarization or Polishing (CMP) process is performed to remove the top portions of the oxide 162 and liner 160, thus leaving an oxide-filled ring-shaped liner region 160A (i.e., ring-shaped in a cross-section perpendicular to the page) that will become the bottom electrode 102. As shown in FIG. 6D, an electrolyte layer 170 (e.g., SiOx/CuSixOy), a top electrode 172 (e.g., PVD Cu), and a top electrode contact 174 (e.g., TaN) are then deposited or formed over the stack. The electrolyte layer 170, top electrode 172, and top electrode contact 174 may then be etched or otherwise processed to produce a desired cell shape.

FIG. 7 illustrates an example resistive memory cell structure 200, according to an example embodiment. As shown, memory cell structure 200 may include a ring-shaped bottom electrode 202 formed in an interlayer dielectric layer 204, an electrolyte layer 206, and top electrode 208 formed over the bottom electrode 202 such that the electrolyte layer 206 is arranged between the bottom electrode 202 and top electrode 208, and bit line(s) 210 connected to the top electrode 208. A bottom electrode contact 212 is connected to a bottom region of the ring-shaped bottom electrode 202. Further, nitride spacers 214 may be formed over sidewalls of bit lines 210, top electrode 208, and electrolyte layer 206, e.g., by a nitride deposit and etch process. A conductive filament 220 is also shown for reference.

In some embodiments the resistive memory cell structure 200 can be formed using two masks. First, a via (or trench) open mask is used, into which a thin TiN layer is deposited, followed by a PECVD oxide fill and CMP process. This forms the bottom electrode 202. Following this, the electrolyte layer 206 (e.g. a thin SiOx layer) is deposited, followed by the top electrode 208 (e.g. Cu/TaN/W), and this stack is then etched with a second mask. Normally a thick Cu film cannot be etched in a plasma, hence a thin (50-300 A) PVD Cu layer may be formed, which can be plasma-etched with this second mask.

As discussed above, the disclosed concepts apply both the metallic filament type CBRAM cells and the vacancy type ReRAM cells. In the disclosed asymmetrical structure, one of electrodes in contact with the electrolyte/insulator is the source of these metallic ions/vacancies, while the other is typically inert.

Various embodiments may provide one or more advantages relative to conventional cell structures and/or formation techniques. For example, the asymmetric structure (e.g., incorporating a ring-shaped bottom electrode) may improve the functionality and reliability of Cu/SiOx based cells by reducing the bottom electrode area in contact with the electrolyte. Thus, the volume in which the number of roots of metallic filaments/vacancy-chain roots can form is greatly reduced over the conventional structures. This may provide various advantages. For example, the asymmetrical structure may provide improve switching characteristics and reliability because there is a far greater likelihood of creating a single, thick filament/vacancy-chain that is more stable for retention purposes. As another example, because the bottom electrode area is reduced, a much higher current density can be achieved for the same current flow. This may allow for a uni-polar operation in switching, i.e., both the set (filament formation) and reset (filament dissolution by joule-heating) can be done at the same voltage polarity. This has been demonstrated on the Cu/SiOx cells, but has needed a much higher current level under reset, the mechanism for dissolution being based on Joule heating rather than an electrolytic reduction of the metallic filament.

1. A resistive memory cell, comprising:
a ring-shaped bottom electrode,
a top electrode, and
an electrolyte layer arranged between the bottom and top electrodes.

2. The cell according to claim 1, comprising, in a plane extending through the ring-shaped bottom electrode, a dielectric material arranged within a circumference defined by the ring-shaped bottom electrode.

3. The cell according to claim 2, wherein the dielectric material comprises an oxide, e.g., SiO₂.

4. The cell according to claim 1, wherein:
the ring-shaped bottom electrode is formed in a substrate, and
a thickness of the ring-shaped bottom electrode in a direction extending in a plane of the substrate is less than three times a thickness of the electrolyte layer in a direction perpendicular to the plane of the substrate.

5. The cell according to claim 4, wherein the thickness of the ring-shaped bottom electrode is less than two times the thickness of the electrolyte layer.

6. The cell according to claim 4, wherein the thickness of the ring-shaped bottom electrode is less than the thickness of the electrolyte layer.

7. The cell according to claim 4, wherein the thickness of the ring-shaped bottom electrode is less than one half the thickness of the electrolyte layer.

8. The cell according to claim 1, wherein the bottom electrode is formed from TiN.

9. The cell according to claim 1, wherein the top electrode is formed from copper.

10. A method for forming a resistive memory cell, comprising:
forming a ring-shaped bottom electrode by a process including:
forming a dielectric layer over a bottom electrode contact,
etching a via in the dielectric layer to expose at least a portion of the bottom electrode contact,
depositing a conductive via liner over the dielectric layer and into the via, the via liner deposited in the via forming a ring-shaped structure in the via and a contact portion in contact with the exposed bottom electrode contact, the ring-shaped structure defining a cavity radially inward of the ring-shaped structure, and
filling the cavity radially inward of the ring-shaped structure with a dielectric fill material,
such that the ring-shaped structure of the via liner forms the ring-shaped bottom electrode,
depositing an electrolyte layer over the bottom electrode, and
depositing a top electrode over the electrolyte layer.

11. The method according to claim 10, wherein the process of forming the bottom electrode further includes removing upper portions of the dielectric fill material and via liner before depositing the electrolyte layer over the bottom electrode.

12. The method according to claim 11, wherein the upper portions of the dielectric fill material and via liner are removed by a chemical mechanical polishing or planarization process.

13. The method according to claim 10, further comprising depositing a top electrode contact over the top electrode.

14. The method according to claim 10, wherein the ring-shaped bottom electrode formed from the via liner comprises TiN.

15. The method according to claim 10, wherein the top electrode is formed from copper.

16. The method according to claim 10, wherein the dielectric fill material comprises an oxide, e.g., SiO₂.

17. The method according to claim 10, wherein a thickness of the ring-shaped bottom electrode in a direction extending in a plane of the electrolyte layer is less than three times a thickness of the electrolyte layer.

18. The method according to claim 17, wherein the thickness of the ring-shaped bottom electrode is less than two times the thickness of the electrolyte layer.

19. The method according to claim 17, wherein the thickness of the ring-shaped bottom electrode is less than the thickness of the electrolyte layer.

20. The method according to claim 17, wherein the thickness of the ring-shaped bottom electrode is less than one half the thickness of the electrolyte layer.
